(19) United States
(12) Patent Application Publication
(10) Pub. No.: US 2005/0263885 A1
(43) Pub. Date: Dec. 1, 2005

(54) Semiconductor device

(75) Inventors: Yoshifumi Nakamura, Hirakata-shi (JP); Junichi Ueno, Ootsu-shi (JP); Hiroyuki Imamura, Settsu-shi (JP); Takayuki Tanaka, Osaka-shi (JP)

Correspondence Address: STEPTOE & JOHNSON LLP, 1330 CONNECTICUT AVENUE, N.W., WASHINGTON, DC, 20036, US

(73) Assignee: Matsushita Elec. Indus.Co., Ltd., Kadoma-shi (JP)

(21) Appl. No.: 11/137,356

(22) Filed: May 26, 2005

(30) Foreign Application Priority Data
May 31, 2004 (JP) 2004-161027
Mar. 24, 2005 (JP) 2005-085076

(51) Int. Cl. H01L 23/495

(52) U.S. Cl. 257/737

(57) ABSTRACT

A semiconductor device in accordance with the present invention is a mounted body of a semiconductor chip with a plurality of electrode pads arranged in a plurality of stages and a tape wiring board, the average pitch of the electrode pads on the entire semiconductor chip can be reduced, while ensuring stable connectivity, by leading together to the outside of the semiconductor chip two or more wirings of the tape wiring board connected to the electrode pads on the inner side between the electrode pads arranged in a row on the outer periphery of the semiconductor chip.

### BACKGROUND OF THE INVENTION

1. Field of the Invention

The present invention relates to a semiconductor device formed by mounting a semiconductor chip on a wiring substrate, and more particularly to an electrode pad configuration thereof.

2. Description of the Related Art

In recent years, the spread of notebook personal computers and liquid-crystal TV created a strong demand for liquid-crystal panels, and accordingly a strong demand was created for semiconductor devices for operating the liquid-crystal panels. Furthermore, a strong need was generated for low-cost liquid-crystal panels and semiconductor devices that will enable a wider spread and lower cost of notebook personal computers. A large number of methods for directly mounting semiconductor devices on glass substrates by using anisotropic electrically conductive sheets, such as TCP (Tape Carrier Package), COF (Chip on Film), or COG (Chip on Glass) were developed. Furthermore, the pitch of electrode pads of semiconductor chips is being progressively reduced with the object of miniaturizing the chip size.

The electrode pad configuration in the conventional semiconductor device will be explained hereinbelow with reference to FIG. 8.

FIG. 8 is a plan view of an electrode pad section in a conventional semiconductor device.

In a semiconductor chip 1 where semiconductor elements are formed, metal bumps 28 are formed on electrode pads 2 with the connection structure in which electrode pads 2 of the outer peripheral portions are arranged alternately in two stages, that is, with a configuration in which the electrode pads 2 are arranged one by one in a zigzag fashion. The metal bumps 28 are connected to wirings 6 or wirings 7 of the wiring board by thermal fusion, and the semiconductor chip 1 is mounted on the wiring board. With such a structure, the electrode pads can be mounted with a higher density than in the case of a single-stage mounting. Furthermore, the electrode pads can be increased in size and mounting ability is improved.

Japanese Patent Application Laid-open No. S62-152154 is an example of reference information representing prior art technology to which the invention of the present application pertains.

However, the problem was that though it was strongly needed to reduce the pitch of electrode pads in the lead-out section and provide for a high-density mounting, while maintaining the joining strength of the semiconductor pitch and wiring boards, specifications for the design spacing of the electrode pads 2 and wirings 6 set larger margins therebetween than the specifications on the spacing between the wirings, thereby making it difficult to increase the mounting density.

### SUMMARY OF THE INVENTION

In order to resolve the problem, it is an object of the present invention to provide a semiconductor device wherein the specification on the design spacing is conformed to and the pitch of electrode pads is reduced, while maintaining the joining strength of the semiconductor chip and wirings of the wiring board.

In order to attain this object, the present invention provides a semiconductor device in which a semiconductor chip with a plurality of electrode pads arranged in a plurality of stages in a plane from the outer periphery of the chip edge inwardly is mounted on a tape wiring board having arranged thereon wirings for connection to the electrode pads, wherein a prescribed spacing determined in advance is provided between any electrode pads disposed in the second and subsequent stages on the outer periphery from the innermost periphery, and a plurality of wirings arranged adjacently to each other among the wirings to be connected to the electrode pads disposed in the second and subsequent stages on the inner side from the outermost periphery are formed in the spacing.

Also provided is a semiconductor device in which a semiconductor chip with a plurality of electrode pads arranged in two stages in a plane from the outer periphery of the chip edge inwardly is mounted on a tape wiring board having arranged thereon wirings for connection to the electrode pads, wherein the prescribed spacing determined in advance is provided between any electrode pads arranged on the outer peripheral side, and a plurality of wirings arranged adjacently to each other among the wirings to be connected to the electrode pads arranged on the inner side are formed in the spacing.

Also provided is a semiconductor device in which a semiconductor chip with a plurality of electrode pads arranged in a plurality of stages in a plane from the outer periphery of the chip edge inwardly is mounted on a tape wiring board having arranged thereon wirings for connection to the electrode pads, wherein the prescribed spacing determined in advance is provided between any electrode pads disposed in the second and subsequent stages on the outer periphery from the innermost periphery, a plurality of wirings arranged adjacently to each other among the wirings to be connected to the electrode pads disposed in the second and subsequent stages on the inner side from the outermost periphery are formed in the spacing, and the width of the region having disposed therein the electrode pads of the second stage from the outermost periphery that are to be connected to the wirings formed in the one spacing is equal to the width of the region in which the electrode pads on the outermost periphery that were disposed on both sides of the spacing are added to the spacing.

Also provided is a semiconductor device in which a semiconductor chip with a plurality of electrode pads arranged in two stages in a plane from the outer periphery of the chip edge inwardly is mounted on a tape wiring board having arranged thereon wirings for connection to the electrode pads, wherein the prescribed spacing determined in advance is provided between any electrode pads arranged on the outer peripheral side, a plurality of wirings arranged adjacently to each other among the wirings to be connected to the electrode pads arranged on the inner side are formed in the spacing, and the width of the region having disposed therein the electrode pads on the inner side that are to be connected to the wirings formed in the one spacing is equal to the width of the region in which the electrode pads on the outer side that were disposed on both sides of the spacing are added to the spacing.

Also provided is a semiconductor device in which a semiconductor chip with a plurality of electrode pads arranged in a plurality of stages in a plane from the outer periphery of the chip edge inwardly is mounted on a tape wiring board having arranged thereon wirings for connection to the electrode pads via metal bumps, wherein the prescribed spacing determined in advance is provided between any electrode pads disposed in the second and subsequent stages on the outer periphery from the innermost periphery, and a plurality of wirings arranged adjacently to each other among the wirings to be connected to the electrode pads disposed in the second and subsequent stages on the inner side from the outermost periphery are formed in the spacing.

Also provided is a semiconductor device in which a semiconductor chip with a plurality of electrode pads arranged in two stages in a plane from the outer periphery of the chip edge inwardly is mounted on a tape wiring board having arranged thereon wirings for connection to the electrode pads via metal bumps, wherein the prescribed spacing determined in advance is provided between any electrode pads arranged on the outer peripheral side, and a plurality of wirings arranged adjacently to each other among the wirings to be connected to the electrode pads arranged on the inner side are formed in the spacing.

Also provided is a semiconductor device in which a semiconductor chip with a plurality of electrode pads arranged in a plurality of stages in a plane from the outer periphery of the chip edge inwardly is mounted on a tape wiring board having arranged thereon wirings for connection to the electrode pads via metal bumps, wherein the prescribed spacing determined in advance is provided between any electrode pads disposed in the second and subsequent stages on the outer periphery from the innermost periphery, a plurality of wirings arranged adjacently to each other among the wirings to be connected to the electrode pads disposed in the second and subsequent stages on the inner side from the outermost periphery are formed in the spacing, and the width of the region having disposed therein the electrode pads of the second stage from the outermost periphery that are to be connected to the wirings formed in the one spacing is equal to the width of the region in which the electrode pads on the outermost periphery that were disposed on both sides of the spacing are added to the spacing.

Also provided is a semiconductor device in which a semiconductor chip with a plurality of electrode pads arranged in two stages in a plane from the outer periphery of the chip edge inwardly is mounted on a tape wiring board having arranged thereon wirings for connection to the electrode pads via metal bumps, wherein the prescribed spacing determined in advance is provided between any electrode pads arranged on the outer peripheral side, a plurality of wirings arranged adjacently to each other among the wirings to be connected to the electrode pads arranged on the inner side are formed in the spacing, and the width of the region having disposed therein the electrode pads on the inner side that are to be connected to the wirings formed in the one spacing is equal to the width of the region in which the electrode pads on the outer side that were disposed on both sides of the spacing are added to the spacing.

Another specific feature is that the wiring pitch of the wirings formed in the spacing is less than the arrangement pitch of the electrode pads disposed in the second and subsequent stages on the inner side from the outermost periphery.

Another specific feature is that a plurality of electrode pads located on the outermost periphery are formed adjacently to each other.

Another specific feature is that the number of the wirings formed in the spacing is four, and the electrode pads located on the outermost periphery provide the spacing to every two thereof.

Another specific feature is that the fluctuation tolerance of electric characteristics of active elements formed below the electrode pads disposed on the outermost periphery is larger than the fluctuation tolerance of electric characteristics of active elements formed below the electrode pads disposed in the second and subsequent stages on the inner side from the outermost periphery.

Another specific feature is that the fluctuation tolerance of electric characteristics of circuit blocks formed below the electrode pads disposed on the outermost periphery is larger than the fluctuation tolerance of electric characteristics of circuit blocks formed below the electrode pads disposed in the second and subsequent stages on the inner side from the outermost periphery.

Another specific feature is that the lead-out direction of the electrode pads of the wirings is perpendicular to a side of the semiconductor chip.

Another specific feature is that the pad size of the electrode pads disposed on the outermost periphery is larger than that of the electrode pads disposed in the second and subsequent stages on the inner side from the outermost periphery.

Another specific feature is that a plurality of electrode pads are connected to one wiring.

Another specific feature is that the distance between the wirings formed in the spacing and the wirings connected to the electrode pads on the outermost periphery is larger than the wiring pitch of the wirings formed in the spacing.

Another specific feature is that there comprised metal bumps electrically insulated from the semiconductor chip on the wirings formed in the spacing.

Another specific feature is that the width of the wirings in the portion to be joined to the electrode pads of the wirings is larger that that of other wirings.

In the semiconductor device in accordance with the present invention, the specification on the design spacing is conformed to and the pitch of electrode pads is reduced, while maintaining the joining strength of the semiconductor chip and wirings of the wiring board.

### BRIEF DESCRIPTION OF THE DRAWINGS

FIG. 1 is a plan view of electrode pad portions in a semiconductor device of Embodiment 1;

FIG. 2 is a cross sectional view of a process illustrating a method for manufacturing the semiconductor device of Embodiment 1;

FIG. 3 is a plan view of electrode pad portions in a semiconductor device of Embodiment 2;

FIG. 4 is a cross sectional view of a process illustrating a method for manufacturing the semiconductor device of Embodiment 2;

FIG. 5 is a plan view of electrode pad portions in a semiconductor device of Embodiment 3;

FIG. 6 is a plan view of electrode pad portions in a semiconductor device of Embodiment 4;

FIG. 7 is a plan view of electrode pad portions in a semiconductor device of Embodiment 5; and

FIG. 8 is a plan view of electrode pad portions in a conventional semiconductor device.

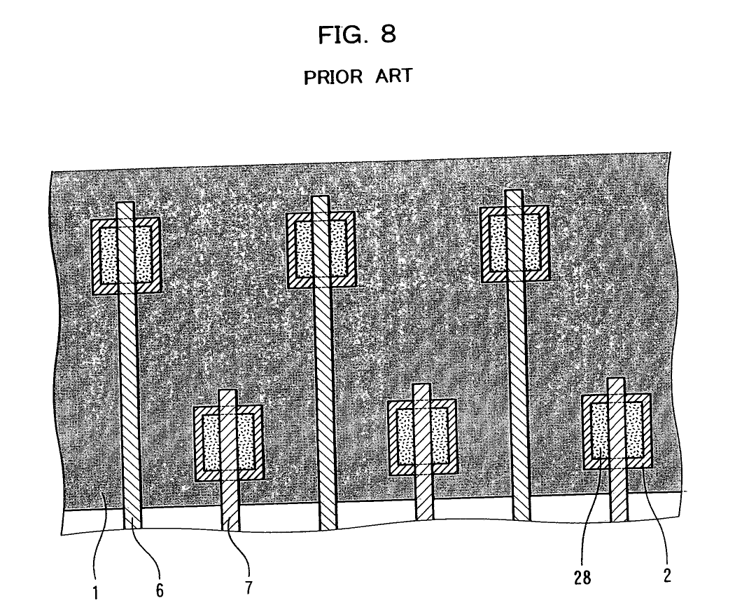

### DESCRIPTION OF THE PREFERRED EMBODIMENTS

The preferred embodiments of the present invention will be described below.

### Embodiment 1

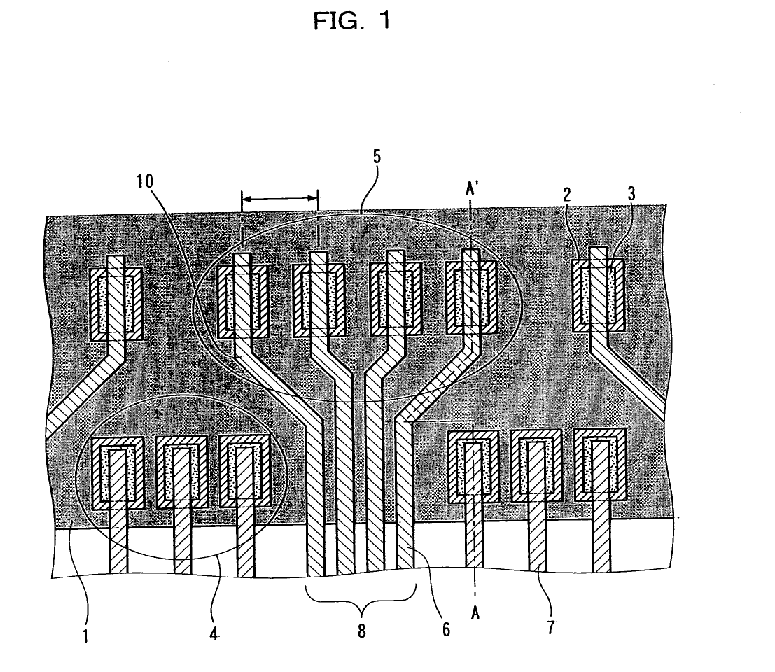

FIG. 1 is a plan view of the electrode pad portion in the semiconductor device of Embodiment 1. It is a plan view illustrating the structure of electrode pad portions which are input/output terminals on a semiconductor chip connected to wirings on a tape wiring board, as viewed from the side of the tape wiring board.

Referring to FIG. 1, the disposition of electrode pads 2 on a semiconductor chip 1 is such that they are formed to have a plane two-stage (double) configuration from the chip edge of the semiconductor chip 1 inwardly, and metal bumps 3 are formed on the electrode pads 2. The electrode pads 2 of each stage are disposed with separation into groups of a plurality of the first electrode pad regions 4 and a plurality of second electrode pad regions 5, the first electrode pad regions 4 being disposed on the outermost periphery of the semiconductor chip 1 and the second electrode pad regions 5 being disposed on the inner side toward the center of the chip. The electrode pads located in each electrode pad region are located generally as close to each other as possible within the range of design specification, and the spacing between the first electrode pad regions 4 enables the formation of a plurality of wirings. The metal bumps 3 are connected together to wirings 6, 7 of the tape wiring board by thermal fusion, thereby mounting the semiconductor chip 1 on the tape wiring board.

In the semiconductor device in accordance with the present invention, the wirings 6 connected to the electrode pads 2 of the second electrode pad region 5 are brought together and led in the form of a multiple-unit wiring 8 to the outside of the semiconductor chip 1 between the first electrode pad regions 4 that have a spacing therebetween that enables multiple wiring. Here, a configuration is shown in which four wirings 6 connected to four electrode pads 2 of the second electrode pad region 5 are passed between the first electrode pad regions 4. The wiring 7 connected to the electrode pad 2 of the first electrode pad region 4 is led out to the outside of the semiconductor chip 1 at least as one wiring, desirably, as a plurality of consecutive wirings. Here, the first electrode pad regions 4 are formed in three electrode pads 2, and the three electrode pads are consecutively led out to the outside of the semiconductor chip 1. In the case where multiple wirings are joined, the joining stress applied to one electrode pad is reduced. However, the number of wirings is not limited to that of the above-described embodiment. Here, the same effect is also produced when the metal bumps 3 are not formed.

It is desirable that the wirings 6, 7 connected to the electrode pads 2 of the first and second electrode pad regions 4, 5 be connected to the metal bumps 3 and be led out perpendicularly to one side of the semiconductor chip 1. Leading them out in the perpendicular direction makes it possible to reduce the pitch of the adjacent electrode pads. Then, they are bent as shown by shape 10 in the converging direction so that the pitch between the wirings 6 becomes the minimum pitch allowed by the design and a multiple-unit wiring 8 of the lead-out portion can be formed. The pitch between the wirings 6 may be other than the minimum pitch allowed by the design, and the pitch of the multiple-unit wiring 8 is less than the electrode pad pitch of the electrode pad region 5. As a result, the region outside the multiple-unit wiring 8 can be used as an electrode pad region 4 on the outer side. Further, in the electrode pad region 5, the wiring 6 protrudes out with respect to the metal bump 3 and is joined thereto, and in the electrode pad 4, the wiring 7 is joined to the metal bump 3, without protruding therefrom. Joining of protruding wiring increases joining strength, but increases the wiring area. The appropriate method is selected by taking into account both the joining strength and the space of the wiring region. In the semiconductor device, the pitch between the wirings is less than the pitch between the electrode pads 2 and wirings 6. Therefore, a method of leading the wirings as a multiple-unit wiring 8 makes it possible to reduce the entire region of the electrode pads 2.

Further, the configuration is preferably such that the fluctuation tolerance of electric characteristics of active elements or circuit blocks (not shown in the figure) disposed and formed below the electrode pad regions 4 on the outer side formed at the semiconductor chip 1 is larger than that of the active elements of circuit blocks (not shown in the figure) disposed and formed below the electrode pad region S on the inner side. This is because heat produced when the electrode pad 2 of the semiconductor chip 1 and wirings 6, 7 of the tape wiring board are connected by thermal fusion causes fluctuations of electric characteristics due to the fact that the stresses generated by the difference in thermal expansion coefficient between the semiconductor chip 1 and the tape wiring substrate corresponds to a rough density of the joint portions of the electrode pads 2. In other words, in the electrode pad region 5, the density of the electrode pads 2 can easily be high and if the pads are densely formed, the stresses are dispersed on the electrode pads and the stress acting on the semiconductor elements located below the electrode pads is reduced. Conversely, in the electrode pad regions 4, the density of the electrode pads 2 can easily be low and if the electrode pads are sparsely formed, the stresses are concentrated in the electrode pads and the stress acting upon the semiconductor elements located under the electrode pads increases. Therefore, the fluctuation tolerance of electric characteristics has to be taken into account in the disposition of semiconductor elements affected by the electric characteristics below the electrode pads.

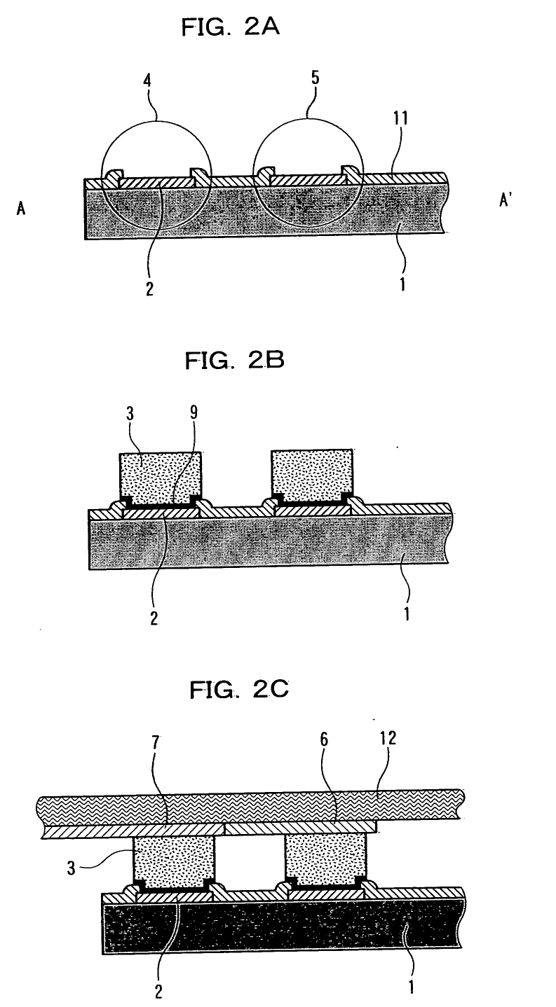

A method for the manufacture of the semiconductor device of the above-described configuration will be explained by using FIG. 2.

FIG. 2 is a process sectional view illustrating a method for the manufacture of the semiconductor device of Embodiment 1 and is a sectional view along a line A-A′ of FIG. 1.

First, as shown in FIG. 2A, electrode pads 2 are disposed in a plurality of stages (two stages in the example shown in the figure) from the chip edge of the semiconductor chip 1 toward the chip center, and electrode pad regions 4 on the outer side and electrode pad regions 5 on the inner side are formed. Here, an electric conductor containing Al as the main component is used as the electrode pad 2, but electric conductors containing Au or Cu as the main component can be also used. The semiconductor chip 1 is coated with an insulating protective film 11, except for openings above the electrode pads 2.

Then, as shown in FIG. 2B, metal bumps 3 are connected to and formed on the electrode pads 2 on the semiconductor chip 1. Here, the metal bumps 3 were formed, but a method using no formation of the metal bumps 3 can be also employed for the connection. Furthermore, when no metal bumps are introduced, Au, Ni, Pd, or the like may be coated on the surface of the electrode pads 2. When the metal bumps 3 are formed, this time, first, a barrier metal layer 9 with the desired thickness is formed by using sputtering technology or the like on the entire surface including the electrode pads 2. Here, this layer was formed from a Ti material, but it may be also formed from other materials such as TiW, W, Pd, and Cr. Furthermore, a technology such as photolithography or electroplating (not shown in the figure) may be used to form the metal bumps 3 in the desired position and to the desired size. When electroplating is employed, the plated layer is deposited by using the barrier metal layer 9 as a seed layer and finally the metal bumps 3 are used as a mask and the barrier metal layer 9 located outside thereof is etched out. More specifically, the electrode pads 2 were formed to a size of 40 μm×60 μm, the metal bumps 3 were formed to a size of 30 μm×50 μm, and the thickness was 17 μm. A metal containing Cu, Au, Sn, Pb, Ag, or Ni as the main component is preferably used for the metal bumps 3.

Then, as shown in FIG. 2C, the electrode pads 2 of the electrode pad regions 5 on the inner side and electrode pad regions 4 on the outer side are respectively electrically joined and connected via the metal bumps 3 to the wiring 7 and wiring 6 located on the tape wiring board 12. A polyimide is preferably used for the tape wiring board, and a metal containing Cu, Au, Sn, Pb, Ag, or Ni as the main component is preferably used as the wiring material. Here, a Sn wiring plated on Cu was used. Joining was conducted by heating under applied pressure and was implemented at a temperature of 400° C.

Because the spacing between the wirings can be less than the spacing between the electrode pads and the wirings, as described above, a spacing in excess of a fixed value can be provided between the locations of electrode pads on the inner side and multiple wirings connecting the electrode pads on he inner side are passed together through that spacing, thereby making it possible to decrease the pitch of the electrode pads of the semiconductor device.

Here, the pitch of the electrode pads in the electrode pad regions 5 and 4 on the inner and outer side was 50 μm and the wiring pitch of the multiple-unit wiring 8 led therefrom was 30 μm, thereby providing for an average electrode pad pitch of about 39 μm.

At this time, it is preferred that the wiring lead-out portions of the wirings 6 and 7 of the tape wiring board 12 connected to the metal bumps 3 be connected perpendicularly to the side of the semiconductor ship 1. As a result, the wiring space can be reduced and the probability of short circuit with the adjacent electrode pad 2 can be reduced. Furthermore, here a configuration of the metal bumps 3 was shown in which the wirings 6 and 7 of the tape wiring board 12 were joined thereto, while protruding therefrom, by joining without bump is also possible. In this case the joining strength decreases, but the wiring region can be reduced and the electrode pad regions can be further miniaturized.

Further, with the object of increasing the joining reliability, the space between the semiconductor chip 1 and tape wiring substrate 12 may be sealed with a resin for reinforcement. As epoxy-based material is preferably used for this purpose.

### Embodiment 2

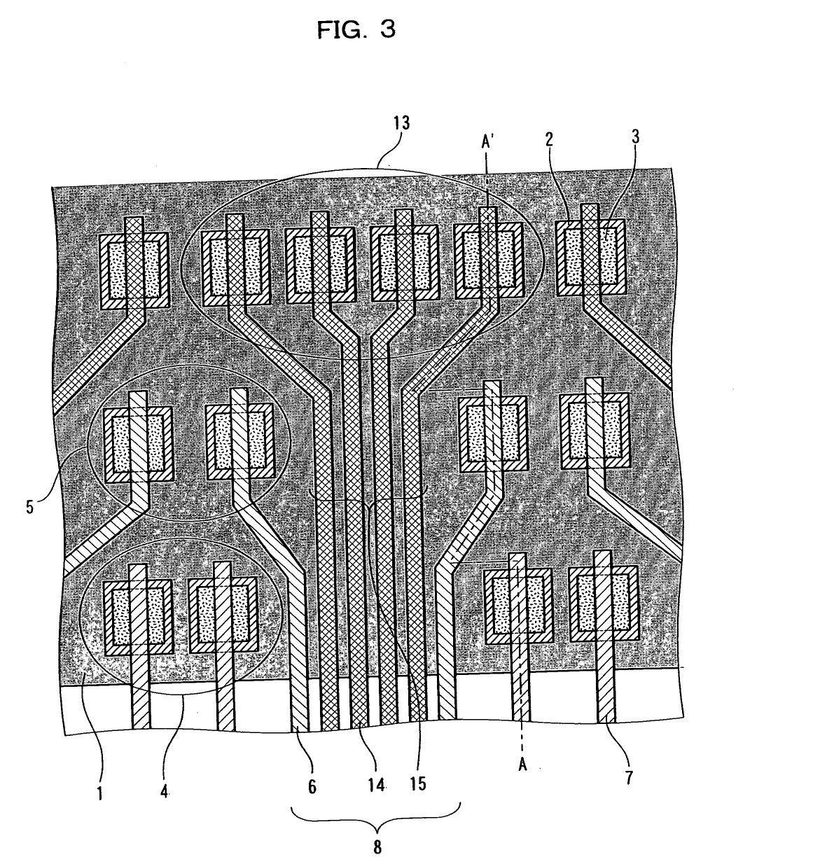

FIG. 3 is a plan view of the electrode pad portion in the semiconductor device of Embodiment 2; it is a plan view showing the structure of the electrode pad portion which is an input/output terminal on the semiconductor chip.

Referring to FIG. 3, the electrode pads 2 located on the semiconductor chip 1 are arranged to have a three-stage (triplet) configuration in a plane from the edge of the semiconductor chip 1 toward the inner zone thereof, and metal bumps 3 are formed on the electrode pads 2. The three-stage configuration arrangement of the electrode pads 2, 3 is in general identical to that of Embodiment 1 and comprises first electrode pad regions 4 arranged in a row on the outermost periphery of the semiconductor chip 1 and second electrode pad regions 5 and third electrode pad regions 13 forming a second stage and a third stage on the inner side toward the chip center. The first electrode pad regions 4 and second electrode pad regions 5, with the exception of the third electrode pad regions 13 on the outermost periphery, are arranged with the prescribed spacing therebetween similarly to the first electrode pad regions 4 in Embodiment 1. The metal bumps 3 are all together connected to the wirings 6, 7, 14 of the tape wiring board by thermal press fusion, and the semiconductor chip 1 is thereby mounted on the tape wiring boards.

The relationship between the electrode pads 2 of the semiconductor chip 1 and the wiring of the tape wiring board is such that the wirings 14 from the third electrode pad region 13 of the third stage are combined together into a multiple-unit wiring 15 composed of a plurality of wiring units and passed between the electrode pads 2 of the second electrode pad regions 5 of the second stage, and the wirings 7 from the second electrode pad region 5 and the multiple-unit wirings 15 are combined together into a multiple-unit wiring 8 led out to the outside of the semiconductor chip 1 between the electrode pads 2 of the first electrode pad region 4. Here, four wirings 14 connected to four electrode pads 2 of the third electrode pad region 13 pass between the electrode pads 2 of the second electrode pad region 5, two wirings 6 connected to the two electrode pads 2 of the second electrode pad region 5 are added thereto, and the multiple-unit wiring 8 composed of six wirings passes between the electrode pads 2 of the first electrode pad region 4. At least one, preferably a plurality of wirings 7 connected to the electrode pad 2 of the first electrode pad region 4 are continuously led out to the outside of the semiconductor chip 1. Here, two wirings are continuously led out to the outside of the semiconductor chip 1. In the case of multiple joints, the joining stress applied to one electrode pad can be reduced. The number thereof is, however, not limited to the above-described embodiments. The same effect is obtained even when no metal bumps 3 are formed.

Further, the wirings 6, 7, and 14 of the tape wiring substrate are connected to the metal bumps 3 present on the electrode pad 2 formed on the semiconductor chip 1 and are preferably led out perpendicularly to the side of the semiconductor chip 1. Leading them out in the perpendicular direction makes it possible to reduce the pitch of the adjacent electrode pads. The wirings 6, 14 that were led out in the perpendicular direction are bent in the converging direction so that the pitch between the wirings becomes the minimum pitch allowed by the design and a multiple-unit wiring 8 of the lead-out portion can be formed thereby. The pitch between the wirings 6, 14 may be other than the minimum pitch allowed by the design, and the pitch of the multiple-unit wiring 8 is preferably less than the electrode pad pitch of the electrode pad regions 4 5.

Further, for the same reason that was explained in Embodiment 1, a configuration is preferred in which the fluctuation tolerance of electric characteristics of active elements (not shown in the figure) formed below the electrode pad regions 4 on the outer side formed at the semiconductor chip 1 be larger than that of the active elements (not shown in the figure) formed below the electrode pad region 13 on the inner side.

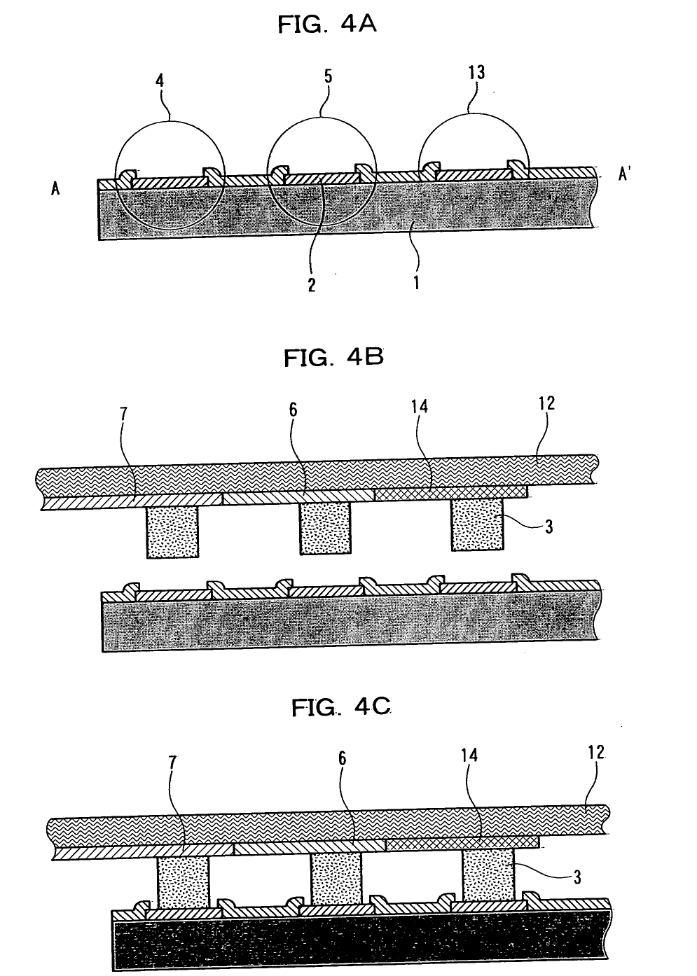

A method for the manufacture of the semiconductor device of the above-described configuration will be described below by using FIG. 4.

FIG. 4 shows a process sectional view illustrating the method for the manufacture of the semiconductor device of Embodiment 2 of the present invention is a sectional view along a line A-A′ of FIG. 3.

First, as shown in FIG. 4A, electrode pads 2 are arranged in a plurality of stages (here, three stages) from the chip edge of the semiconductor chip 1 toward the chip center, and the electrode pad regions 4, 5, and 13 are formed. Here, an electric conductor containing Al as the main component is used as the chip electrodes 2, but electric conductors containing Au or Cu as the main component can be also used. The surface of the electrode pads 2 may be coated with Au, Ni, Pd, or the like. As for the size, the electrode pads were formed to a size of 40 μm×60 μm.

Then, as shown in FIG. 4B, a tape wiring board 12 having metal bumps 3 formed in the positions corresponding to the electrode pads 2 was prepared. In the method for the manufacture of the semiconductor device of this embodiment, the case is explained where the metal bumps 3 are formed in advance so as to be connected to the wirings of the tape wiring board 12, by contrast with Embodiment 1.

Here, the tape wiring board 12 having the metal bumps 3 is formed by repeatedly subjecting a base material in which a metal foil is formed on the front surface of the tape wiring board 12 to multiple cycles of photolithography and etching and forming the described wirings 6, 7, 14 and metal bumps 3 on the wirings. A layer of a dissimilar metal may be formed by electroless plating or the like on the surface of the metal bump 3. A polyimide is preferably used for the tape wiring substrate 12. A metal containing Cu, Au, Sn, Pb, Ag, or Ni as the main component is preferably used as a material for the wirings and metal bumps. This time, a tape wiring board 12 was used in which Cu wirings were plated with Au. Here, the thickness of the wirings was 10 μm, the thickness of the metal bumps 3 was 5 μm, and the size of the metal bumps was 30 μm×50 μm.

Further, as shown in FIG. 4C, the electrode pads 2 of the electrode pad regions 5, 13 on the inner side and electrode pad region 4 on the outer side are electrically joined and connected via the metal bumps 3 to the wiring 7, wiring 13, and wiring 6, respectively, on the tape wiring board 12. The joining method of pressurization and heating was employed at 300° C.

As described hereinabove, even with the configuration in which the electrode pads are arranged in three or more stages, the pitch of the electrode pads of the semiconductor device can be reduced in the same manner as in Embodiment 1 by providing regions with a wide spacing in the locations of the electrode pads of the outermost stage and passing together therethrough the wirings from the electrode pads on the inner side.

Here, the average electrode pad pitch can be made about 35 μm by employing a pitch of the electrode pads 5 on the inner side and outer side of 50 μm and a pitch of the wirings 8 that are led out together of 30 μm.

Furthermore, from the standpoint of increasing the joining reliability, it is preferred that the space between the semiconductor chip 1 and tape wiring board 2 be filled with a resin for reinforcement. Am epoxy-based material is preferably used for this purpose.

### Embodiment 3

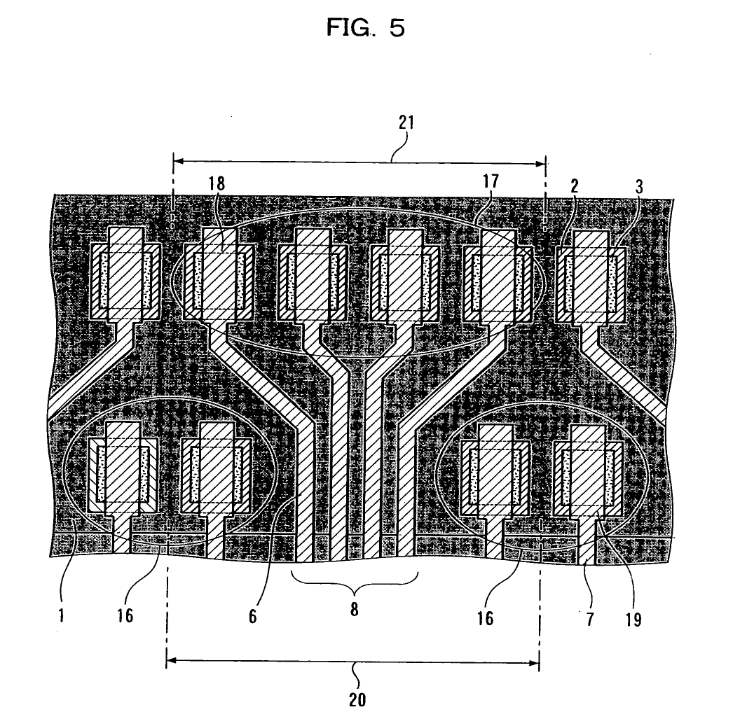

FIG. 5 is a plan view of the electrode pad portions in the semiconductor device of Embodiment 3; it is a plan view showing the structure of the electrode pad portion which is an input/output terminal on the semiconductor chip.

As shown in FIG. 5, the semiconductor device of Embodiment 3 is basically identical to that of Embodiment 1, the electrode pads 2 located on the semiconductor chip 1 are disposed as a two-stage configuration from the chip end of the semiconductor chip 1 and metal bumps 3 are formed on the electrode pad 2. The two-stage configuration of the electrode pads 2 is composed of first electrode pad regions 16 arranged in a row on the outermost periphery of the semiconductor chip 1 and second electrode pad regions 17 on the inner side toward the chip center. The metal bumps 3 are together connected to the wirings 6, 7 of the tape wiring substrate by thermal fusion, and the semiconductor chip 1 is thereby mounted on the tape wiring substrate. In the present embodiment, as shown in FIG. 5, the width of the wirings 6 after they are led out from the metal bumps 3 is formed to be less than the width of the wirings 18 of the tape wiring substrate connected to the metal bumps 3 present on the electrode pads 2. As a result, a narrower pitch of the led-out portions can be realized, while ensuring the joining strength of the joint portion with good stability. The wirings 18 of the tape wiring substrate that are connected to the electrode pads 2 of the semiconductor chip 1 are led out as the wirings 6, combined together as a multiple-unit wiring 8 and led out to the outside of the semiconductor chip 1. Furthermore, the region width 21 of the electrode pad regions 17 located on the inner side is almost equal to the region width 20 including the multiple-unit wiring 8 and the electrode pads 2 of the outermost portion of the electrode pad regions 16 on the outer side that are disposed on both sides of the multiple-unit wiring. As a result, the electrode pad region can be effectively used, the pitch of the electrode pads can be reduced, the density and uniformity of the disposition of the electrode pads 2 located on the inner side and electrode pads 2 located on the outer side can be improved, and stresses generated due to the difference in thermal expansion coefficient between the tape wiring board and semiconductor chip during joining can be dispersed.

Furthermore, in the case where the first electrode pads 16 located on the outer periphery are formed by two or more electrode pads 2, the configuration is even more effective with respect to stresses that are especially strongly generated in the outer peripheral portions. When there is only one electrode pad 2, because the joining surface area is reduced, the electrode pad is sometimes broken by stresses, but this problem is resolved with two or more electrode pads. However, though providing many first electrode pads on the outer periphery is effective against the stresses, it is undesirable from the standpoint of reducing the wiring pitch. Increasing the number of the second electrode pads on the inner side reduces the pitch, but in this case a large number of wirings are disposed between the first electrode pads on the outer side, thereby expanding the space between the electrode pads. For this reason, the pitch is increased, the stress applied to one electrode pad rises and the electrode pad can be broken. As an assembly, it is effective to allocate four second electrode pads located on the inner side to two first electrode pads located on the outer side. Here, the same effect is obtained when no metal bumps 3 are formed.

In the present embodiment, a two-stage configuration of electrode pads was explained by way of an example, but a configuration with three and more stages is also possible, similarly to Embodiment 2.

The above-described semiconductor device can be manufactured by the manufacturing method identical to that of Embodiment 1 or 2 and the explanation thereof is omitted.

### Embodiment 4

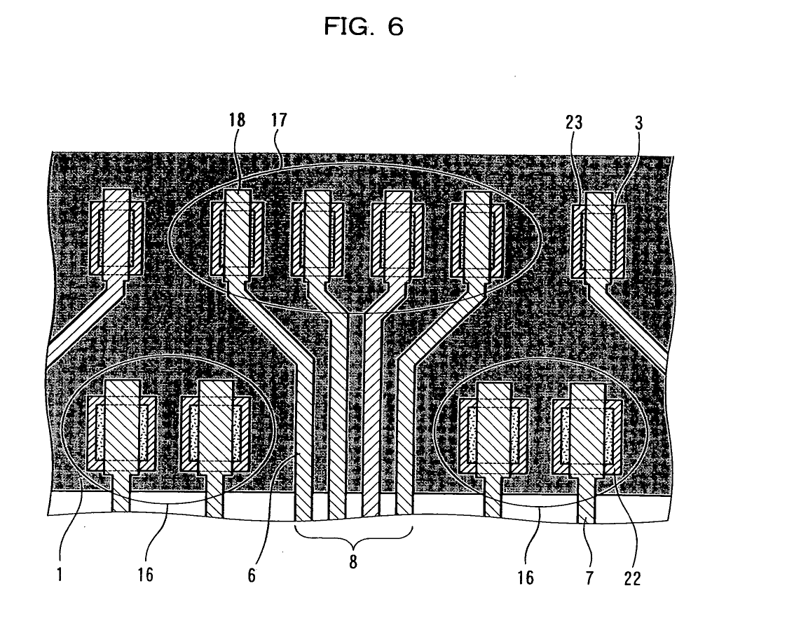

FIG. 6 is a plan view of the electrode pad portions in the semiconductor device of Embodiment 4; it is a plan view showing the structure of the electrode pad portion which is an input/output terminal on the semiconductor chip.

As shown in FIG. 6, the semiconductor device of Embodiment 4 is basically identical to that of Embodiment 1, the electrode pads located on the semiconductor chip 1 are disposed as a two-stage configuration from the chip end of the semiconductor chip 1 and metal bumps 3 are formed on the electrode pads 22 and 23. The two-stage configuration of the electrode pads is composed of first electrode pad regions 16 arranged in a row on the outermost periphery of the semiconductor chip 1 and second electrode pad regions 17 on the inner side toward the chip center. The metal bumps 3 are together connected to the wirings 6, 7 of the tape wiring substrate by thermal fusion, and the semiconductor chip 1 is thereby mounted on the tape wiring substrate. In the present embodiment, as shown in FIG. 6, the width of the wirings 6 after they are led out from the metal bumps 3 is formed to be less than the width of the wirings 18 of the tape wiring substrate connected to the metal bumps 3 present on the electrode pads. As a result, a narrower pitch of the led-out portions can be realized, while ensuring the joining strength of the joint portion with good stability. The wirings 18 of the tape wiring substrate that are connected to the electrode pads 22, 23 of the semiconductor chip 1 are led out as the wirings 6, combined together as a multiple-unit wiring 8 and led out to the outside of the semiconductor chip 1. Furthermore, the size of the first electrode pads 22 arraigned in a row on the outermost periphery is larger than the size of the second electrode pads 23 located on the inner side. As a result, the pitch of the electrode pads can be reduced and a sufficient strength can be ensured against stresses caused by the difference in thermal expansion coefficient between the tape wiring board and semiconductor chip during joining. Further, reducing the size of the electrode pads 23 located on the inner side can also decrease the effect of joining on the semiconductor element. Here, the same effect is obtained when no metal bumps 3 are formed.

In the present embodiment, a two-stage configuration of electrode pads was explained by way of an example, but a configuration with three and more stages is also possible, similarly to Embodiment 2.

The above-described semiconductor device can be manufactured by the manufacturing method identical to that of Embodiment 1 or 2 and the explanation thereof is omitted.

### Embodiment 5

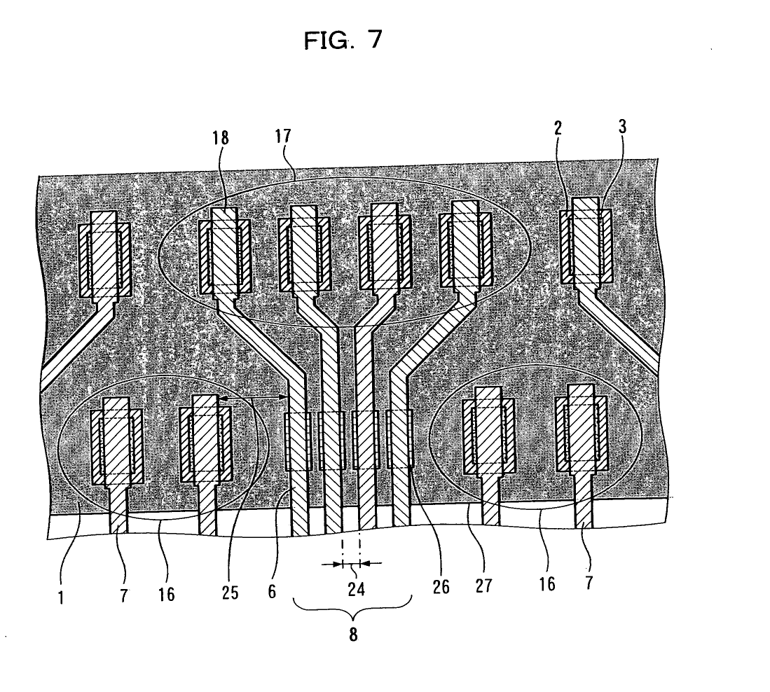

FIG. 7 is a plan view of the semiconductor device of Embodiment 5; it is a plan view showing the structure of the electrode pad portion which is an input/output terminal on the semiconductor chip.

As shown in FIG. 7, the semiconductor device of Embodiment 4 is basically identical to that of Embodiment 1, the electrode pads located on the semiconductor chip 1 are disposed as a two-stage configuration from the chip end of the semiconductor chip 1 and metal bumps 3 are formed on the electrode pads 2. The two-stage configuration of the electrode pads is composed of first electrode pad regions 16 arranged in a row on the outermost periphery of the semiconductor chip 1 and second electrode pad regions 17 on the inner side toward the chip center. The metal bumps 3 are together connected to the wirings 6, 7 of the tape wiring substrate by thermal fusion, and the semiconductor chip 1 is thereby mounted on the tape wiring substrate. In the present embodiment, as shown in FIG. 7, the width of the wirings 6 after they are led out from the metal bumps 3 is formed to be less than the width of the wirings 18 of the tape wiring substrate connected to the metal bumps 3 present on the electrode pads. As a result, a narrower pitch of the led-out portions can be realized, while ensuring the joining strength of the joint portion with good stability. The wirings 18 of the tape wiring substrate that are-connected to the electrode pads 2 of the semiconductor chip 1 are led out as the wirings 6, combined together as a multiple-unit wiring 8 and led out to the outside of the semiconductor chip 1. Here, the same effect is obtained when no metal bumps 3 are formed.

Further, protruding electrodes 26 other than the electrode pads are formed on the wirings 6 joined to the electrode pads located on the inner side. As a result, the pitch of electrode pads can be reduced, slackening of the tape wiring board can be prevented, and electric short circuiting caused by contact of the wirings and an edge portion 27 of the semiconductor chip resulting from deflection can be avoided. The protruding electrodes 26 may be provided without electric joining to the semiconductor chip 1, but it is preferred that they be electrically joined thereto to avoid the formation of unnecessary electrode pads.

It is also preferred that a spacing 25 between the wirings 6 in close proximity to the wirings 7 connected to the electrode pads on the outer periphery be larger than a spacing 24 between the wirings 6 disposed as multiple unit in the first electrode pad region 16 on the outer side. The advantage of such configuration is that electric short circuit caused by the displacement of the wirings and semiconductor chip during joining can be easier prevented. Because the collected wirings 6 are the wirings on the tape wiring board, the displacement can be prevented and the spacing can, therefore, be decreased.

In the present embodiment, a two-stage configuration of electrode pads was explained by way of an example, but a configuration with three and more stages is also possible, similarly to Embodiment 2.

The above-described semiconductor device can be manufactured by the manufacturing method identical to that of Embodiment 1 or 2 and the explanation thereof is omitted.

As described hereinabove, the wirings of a tape wiring board that can be formed to have a comparatively fine size are together led out from the electrode pads located on the inner side to the outside of the semiconductor chip. As a result, though the spacing of the electrode pads on the inner side is increased and they are disposed with a large pitch, the average pitch of the electrode pads of the entire structure can be reduced.

1. A semiconductor device in which a semiconductor chip having a plurality of electrode pads is mounted on a tape wiring board having wirings arranged thereon for connection to the electrode pads, the electrode pads being arranged in a plurality of stages in a plane inwardly from the outer periphery of the chip edge, wherein
a prescribed spacing determined in advance is provided between any electrode pads disposed in the second and subsequent stages on the outer periphery from the innermost periphery, and
a plurality of wirings arranged adjacently to each other among the wirings to be connected to the electrode pads disposed in the second and subsequent stages on the inner side from the outermost periphery are formed in the spacing.

2. A semiconductor device in which a semiconductor chip having a plurality of electrode pads is mounted on a tape wiring board having wirings arranged thereon for connection to the electrode pads, the electrode pads being arranged in two stages in a plane inwardly from the outer periphery of the chip edge, wherein
a prescribed spacing determined in advance is provided between any electrode pads arranged on the outer peripheral side, and
a plurality of wirings arranged adjacently to each other among the wirings to be connected to the electrode pads arranged on the inner side are formed in the spacing.

3. A semiconductor device in which a semiconductor chip having a plurality of electrode pads is mounted on a tape wiring board having wirings arranged thereon for connection to the electrode pads, the electrode pads being arranged in a plurality of stages in a plane inwardly from the outer periphery of the chip edge, wherein
a prescribed spacing determined in advance is provided between any electrode pads disposed in the second and subsequent stages on the outer periphery from the innermost periphery,
a plurality of wirings arranged adjacently to each other among the wirings to be connected to the electrode pads disposed in the second and subsequent stages on the inner side from the outermost periphery are formed in the spacing, and
a width of the region having disposed therein the electrode pads of the second stage from the outermost periphery to be connected to the wirings formed in the one spacing is equal to the width of the region in which the electrode pads on the outermost periphery that were disposed on both sides of the spacing are added to the spacing.

4. A semiconductor device in which a semiconductor chip having a plurality of electrode pads is mounted on a tape wiring board having wirings arranged thereon for connection to the electrode pads, the electrode pads being arranged in two stages in a plane inwardly from the outer periphery of the chip edge, wherein
a prescribed spacing determined in advance is provided between any electrode pads arranged on the outer peripheral side,
a plurality of wirings arranged adjacently to each other among the wirings to be connected to the electrode pads arranged on the inner side are formed in the spacing, and
a width of the region having disposed therein the electrode pads on the inner side that are to be connected to the wirings formed in the one spacing is equal to the width of the region in which the electrode pads on the outer side that were disposed on both sides of the spacing are added to the spacing.

5. A semiconductor device in which a semiconductor chip having a plurality of electrode pads is mounted on a tape wiring board having wirings arranged thereon for connection to the electrode pads via metal bumps, the electrode pads being arranged in a plurality of stages in a plane inwardly from the outer periphery of the chip edge, wherein
a prescribed spacing determined in advance is provided between any electrode pads disposed in the second and subsequent stages on the outer periphery from the innermost periphery, and
a plurality of wirings arranged adjacently to each other among the wirings to be connected to the electrode pads disposed in the second and subsequent stages on the inner side from the outermost periphery are formed in the spacing.

6. A semiconductor device in which a semiconductor chip having a plurality of electrode pads is mounted on a tape wiring board having wirings arranged thereon for connection to the electrode pads via metal bumps, the electrode pads being arranged in two stages in a plane inwardly from the outer periphery of the chip edge, wherein
a prescribed spacing determined in advance is provided between any electrode pads arranged on the outer peripheral side, and
a plurality of wirings arranged adjacently to each other among the wirings to be connected to the electrode pads arranged on the inner side are formed in the spacing.

7. A semiconductor device in which a semiconductor chip having a plurality of electrode pads is mounted on a tape wiring board having wirings arranged thereon for connection to the electrode pads via metal bumps, the electrode pads being arranged in a plurality of stages in a plane inwardly from the outer periphery of the chip edge, wherein
a prescribed spacing determined in advance is provided between any electrode pads disposed in the second and subsequent stages on the outer periphery from the innermost periphery,
a plurality of wirings arranged adjacently to each other among the wirings to be connected to the electrode pads disposed in the second and subsequent stages on the inner side from the outermost periphery are formed in the spacing, and
a width of the region having disposed therein the electrode pads of the second stage from the outermost periphery that are to be connected to the wirings formed in the one spacing is equal to the width of the region in which the electrode pads on the outermost periphery that were disposed on both sides of the spacing are added to the spacing.

8. A semiconductor device in which a semiconductor chip having a plurality of electrode pads is mounted on a tape wiring board having wirings arranged thereon for connection to the electrode pads via metal bumps, the electrode pads being arranged in two stages in a plane inwardly from the outer periphery of the chip edge, wherein
a prescribed spacing determined in advance is provided between any electrode pads arranged on the outer peripheral side, and
a plurality of wirings arranged adjacently to each other among the wirings to be connected to the electrode pads arranged on the inner side are formed in the spacing, and
a width of the region having disposed therein the electrode pads on the inner side that are to be connected to the wirings formed in the one spacing is equal to the width of the region in which the electrode pads on the outer side that were disposed on both sides of the spacing are added to the spacing.

9. The semiconductor device according to claim 1, wherein a wiring pitch of the wirings formed in the spacing is less than an arrangement pitch of the electrode pads disposed in the second and subsequent stages on the inner side from the outermost periphery.

10. The semiconductor device according to claim 1, wherein a plurality of electrode pads located on the outermost periphery are formed adjacently to each other

11. The semiconductor device according to claim 1, wherein the number of the wirings formed in the spacing is four, and the electrode pads located on the outermost periphery provide the spacing to every two thereof.

12. The semiconductor device according to claim 1, wherein a fluctuation tolerance of electric characteristics of active elements formed below the electrode pads disposed on the outermost periphery is larger than a fluctuation tolerance of electric characteristics of active elements formed below the electrode pads disposed in the second and subsequent stages on the inner side from the outermost periphery.

13. The semiconductor device according to claim 1, wherein a fluctuation tolerance of electric characteristics of circuit blocks formed below the electrode pads disposed on the outermost periphery is larger than a fluctuation tolerance of electric characteristics of circuit blocks formed below the electrode pads disposed in the second and subsequent stages on the inner side from the outermost periphery.

14. The semiconductor device according to claim 1, wherein a lead-out direction of the electrode pads of the wirings is perpendicular to a side of the semiconductor chip.

15. The semiconductor device according to claim 1, wherein each electrode pads disposed on the outermost periphery has a size larger than that of the electrode pads disposed in the second and subsequent stages on the inner side from the outermost periphery.

16. The semiconductor device according to claim 1, wherein a plurality of electrode pads are connected to one wiring.

17. The semiconductor device according to claim 1, wherein a distance between the wirings formed in the spacing and the wirings connected to the electrode pads on the outermost periphery is larger than a wiring pitch of the wirings formed in the spacing.

18. The semiconductor device according to claim 1, comprising metal bumps electrically insulated from the semiconductor chip on the wirings formed in the spacing.

19. The semiconductor device according to claim 1, wherein a width of the wirings in a portion to be joined to the electrode pads of the wirings is larger that that of the other portion of the wirings.
